(19) United States
(12) Patent Application Publication
(10) Pub. No.: US 2025/0271520 A1
(43) Pub. Date: Aug. 28, 2025

(54) SHORT-BORE MRI SYSTEM WITH NON-SPHERICAL FIELD OF VIEW

(71) Applicant: SUPERCONDUCTING SYSTEMS, INC., Billerica, MA (US)

(72) Inventors: Marc Ray Buntaine, Pocasset, MA (US); Shahin Pourrahimi, Brookline, MA (US); Jeffrey Philip Freidberg, Belmont, MA (US); Kasra Amir Pourrahimi, Brighton, MA (US)

(21) Appl. No.: 18/817,656

(22) Filed: Aug. 28, 2024

Related U.S. Application Data
(60) Provisional application No. 63/558,810, filed on Feb. 28, 2024.

(51) Int. Cl. G01R 33/38; G01R 33/385; G01R 33/389

(52) U.S. Cl. CPC G01R 33/3804; G01R 33/3806; G01R 33/3852; G01R 33/389; G01R 33/3856

(57) ABSTRACT

The present disclosure provides short-bore magnetic resonance imaging (MRI) systems that produce a non-spherical field of view (FOV). Further, methods for producing a non-spherical field of view are provided. The MRI system includes electromagnetic coils arranged around a magnet opening with a length of 100 cm or less. The electromagnetic coils are configured to generate a static magnetic field within a non-spherical FOV that has a measure of homogeneity of 100 parts per million or better.

### STATEMENT REGARDING FEDERALLY SPONSORED RESEARCH

The present application claims priority to U.S. Provisional Patent Application No. 63/558,810, filed Feb. 28, 2024, the entire contents of which are hereby incorporated by reference.

### BACKGROUND

A standard magnetic resonance imaging (MRI) system includes a magnet that provides a constant, spatially homogenous magnetic field. The magnet is the largest component of an MRI system that typically makes the overall system large and expensive to site and maintain. Reducing the scanner bore length or increasing the inner patient bore diameter is challenging for many reasons. Shortening the scanner bore length may reduce the imaging volume that has sufficient homogeneity for standard imaging methods, the overall homogeneity of the field, the overall field strength, or a combination thereof. However, most clinical imaging paradigms require a large imaging field of view with high magnetic field homogeneity and field strength. Magnet design is further constrained by Lorentz forces experienced by the coils; the high field strengths produced near the coils, which can decrease the maximum electrical current that can flow through the coil; and the desire to reduce fringe fields outside of the scanner bore. With all these constraints in mind, magnets are typically designed by carefully placing discrete electromagnetic coils, with each coil having a specific coil current density, in a space surrounding the bore of the magnet system. Such an arrangement is optimized in order to achieve a desired field strength and homogeneity target within a spherical imaging volume of characteristic diameter at the center of the scanner bore. This spherical space is referred to as the DSV, for diameter of spherical volume. The DSV typically provides sufficient coverage for most anatomical regions (e.g., head, heart, etc.) to fit within the region of sufficiently homogeneous magnetic field. However, as the desired uses of MRI continue to expand, there is a need to create new MRI systems that historically have been understood not to be possible due to the constraints.

### SUMMARY OF THE DISCLOSURE

In some aspects, an MRI system is provided. The MRI system has a magnet opening with a ratio of an opening length over an opening diameter of less than 1.2. The MRI system also includes several electromagnetic coils that are configured to generate a static magnetic field within a field of view of a non-spherical shape. Within the FOV, the static magnetic field has a measure of homogeneity better than 100 parts per million.

In other aspects, a method for producing a static magnetic field is provided. The method includes using a computer system to define an imaging field of view with a non-spherical shape and define a target static field strength. The method further includes using the computer system to calculate a field produced by electromagnetic coils. Each of the electromagnetic coils has a current, a width, a position, an inner radius, and an outer radius. The method further includes using the computer system to reduce an inhomogeneity of the calculated field by adjusting at least one of the current, width, position, inner radius, or outer radius of each of the electromagnetic coils.

In other aspects, an MRI system is provided. The MRI system includes electromagnetic coils arranged around a magnet opening with a length of 100 cm or less. The electromagnetic coils are configured to generate a static magnetic field within a non-spherical FOV that has a measure of homogeneity of 100 parts per million or better.

In other aspects, a whole-body magnetic resonance imaging (MRI) system for humans is provided. The MRI system includes a magnet opening with a length of less than 100 cm. The MRI system also includes several electromagnetic coils that are configured to generate a static magnetic field within a field of view of a non-spherical shape. Within the FOV, the static magnetic field has a measure of homogeneity better than 100 parts per million.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example short-bore magnetic resonance imaging system (MRI) in accordance with some aspects of the present disclosure.

FIG. 2A illustrates a perspective view of an example magnet system that may be configured to produce a magnetic field within a non-spherical or an ellipsoid effective field of view (FOV) in accordance with some aspects of the present disclosure.

FIG. 2B illustrates a side view of an example magnet system that may be configured to produce a magnetic field within a non-spherical or an ellipsoid effective FOV in accordance with some aspects of the present disclosure.

FIG. 2C illustrates a scanner system, which may include the magnet system of FIGS. 2A-2B.

FIG. 2D illustrates parameters of an ellipsoidal non-spherical FOV.

FIG. 2E illustrates parameters of a spheroidal non-spherical FOV.

FIG. 3 is a flowchart outlining the steps of an example process for designing a short-bore magnet system.

FIG. 4 is a flowchart that outlines the steps of an example process for tuning the magnet system design in accordance with some aspects of the present disclosure.

FIG. 5 is a block diagram of an example magnetic resonance imaging (“MRI”) system that can implement the methods described in the present disclosure.

FIG. 6 is a block diagram of an example short-bore system that can implement the methods of the present disclosure.

FIG. 7 is a block diagram of example components that can implement the system of FIG. 6.

### DETAILED DESCRIPTION

Before any aspects of the present disclosure are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

In general, “field of view (FOV)” can have several different meanings within the field of magnetic resonance imaging (MRI). For the purposes of this disclosure, FOV, effective FOV, imaging FOV, magnet FOV, and scanner FOV may refer to a physical volume characterized by a magnetic field produced by the magnet system in use. The boundaries of such volume can be defined based on a target field strength and target homogeneity level produced by the magnet system within the volume. Alternatively, acquisition FOV may refer to a volume in which imaging data will be acquired during data acquisition. For example, the acquisition FOV can be defined by a user during an imaging session. Such acquisition FOV can be used to define a k-space sampling pattern (e.g., Aky) and spatial encoding magnetic field gradients during image or data acquisition. Typically, an acquisition FOV will be constrained by the magnet FOV in order to produce high-quality images within a volume of sufficient homogeneity.

Similarly, scanner bore, system bore, or patient bore, generally, refers to the longitudinal passage extending through the MRI system designed to receive the patient for imaging in the MRI system. Thus, the scanner bore is typically defined by the housing. Cryostat bore refers to the channel formed within the chamber or cryostat. On the other hand, magnet opening refers to the space annularly surrounded by the magnet elements of the MRI system. In this way, the width of the magnet opening is limited by the inner radius of a so-called “coil space” or the minimum inner radius of the magnet elements. Similarly, the length of the magnet opening is limited by the length of the coil space along the scanner axis (e.g., z). The length of the coil space can also be referred to as a coil span (e.g., along z).

Homogeneity refers to the uniformity of the achieved or simulated main magnetic field. Typically, homogeneity is descried for a specified region or volume, such as a FOV or imaging volume. Homogeneity is typically described in parts per million (ppm), which describes the maximum difference in field strength across the specified region. As a non-limiting example, the homogeneity level can be defined in ppm as: 1000000*(max(B)−min(B))/median(B)), where B describes the field strength at each point in space on the surface of the specified region (e.g., ellipsoid FOV) or within the specified region. In this way, homogeneity is often described in terms of “inhomogeneity.” For example, as homogeneity increases, inhomogeneity measured in ppm decreases. Thus, “better” homogeneity is characterized by a smaller ppm value, while “worse” homogeneity is characterized by a larger ppm value.

Reducing the bore length of an MRI scanner could reduce the overall cost and space required to install and run the scanner, increasing scanner flexibility and access (e.g., for rural areas, smaller clinics, developing countries, etc.). Smaller MRI scanners may be made portable, which can be advantageous for several clinical applications. For example, portable MRI scanners can be moved to a patient in critical condition in the intensive care unit, limiting the distance the patient needs to be transferred. Moreover, portable scanners can be used intraoperatively to monitor progress or success of surgery. For example, imaging can be performed to confirm tumor resection, ablation, or biopsy while the patient is still on the operating table. Intraoperative imaging may also be used to guide procedures such as tumor resection, ablation, biopsy, deep brain stimulation, and more. Portable MRI scanners could also be brought into developing countries or areas experiencing natural disasters or war, for example. Shortening the scanner bore length can also help decrease claustrophobia, which may improve patient compliance, reducing recall rate and motion in the images.

Reducing the scanner bore length requires a reduction of the coil span, and thus the magnet opening length. However, reducing the coil span while maintaining a patient bore diameter capable of whole-body imaging (e.g., 60-70 cm) and sufficient image quality is challenging due to several constraints of magnet design, such as field strength, imaging volume extent, field homogeneity, fringe fields, Lorentz forces, cost, and so forth.

The present disclosure provides a system for magnetic resonance imaging (MRI) that advantageously has a short coil span and magnet opening length, which can allow for the scanner to have a short scanner bore length. As non-limiting examples, the short magnet opening length may be defined as <145 cm, <125 cm, <100 cm, <80 cm, <75 cm, <50 cm, <40 cm, <30 cm, and so forth. As another non-limiting example, the short magnet opening length may be defined as 70-80 cm. The short coil span and magnet opening length can be achieved by relaxing the constraint of the imaging volume or effective field of view (FOV). For example, the effective FOV can be defined as a non-spherical volume. In some implementations, the non-spherical volume is an ellipsoid.

Moreover, the reduction of the scanner bore length is practically limited by tradeoffs with bore opening width (e.g., diameter) and the strength and homogeneity of the main magnetic field. Producing a higher-field magnet is often achieved using larger magnet components or magnet elements (e.g., thicker, wider, or both). These larger components typically provide more efficient field production in terms of space, materials, weight, and power. Moreover, the thicker and/or longer coils are often placed with larger spaces between coils (e.g., along the length of the magnet, annularly, or both) due to implications on the peak fields, inter-coil forces, and fringe fields. Thus, increasing the magnet field strength is often associated with longer bore lengths and smaller bore diameters. For example, reducing the scanner bore length for a given field strength and homogeneity may be achieved in practice by reducing the bore diameter. Similarly, reducing the scanner bore length for a given bore diameter may be achieved in practice by reducing the field strength.

Thus, the present disclosure can provide systems and methods for relaxing the tradeoff between the field strength and overall magnet opening size. The magnet opening size can be described as a ratio (RMO) of length to width of the magnet opening. It may be desirable to reduce Rmo of a magnet system by reducing the length of the magnet opening, increasing the width of the magnet opening, or a combination thereof. For example, such reduction in RMO can reduce claustrophobia in patients.

In some configurations, the present disclosure can provide a whole-body magnet system with R_{MO}≤5. In preferable configurations, the present disclosure can provide a whole-body magnet system with R_{MO}≤4, R_{MO}≤3, R_{MO}≤2, ≤R_{MO}≤1.5, R_{MO}≤1.2, R_{MO}≤ 1, R_{MO}≤0.8, R_{MO}≤0.7. Such constraints may be related to the system's field strength and homogeneity. As non-limiting examples, the system may be described as having a homogeneity of at least (better than) 10 ppm, 5 ppm, or 1 ppm with R_{MO}≤0.8 for B₀≤0.5 T, RMo≤1.2 for 0.5 T≤B₀≤1.5 T, R_{MO}≤2 for 3 T≤B₀≤4.5 T, R_{MO}≤2.8 for 4.5 T≤B₀≤7 T, or R_{MO}≤4 for 7 T≤B₀≤11.5 T. R_{MO} can be further reduced for more relaxed homogeneity constraints (e.g., 100 ppm).

Typical whole-body human MRI scanners are developed by optimizing the magnet performance (e.g., field strength and homogeneity of the static main magnetic field) over a spherical FOV in the center of the magnet opening, referred to as diameter of spherical volume (DSV), using spherical harmonics. The spherical FOV is typically assumed to be a ˜40 to 50 cm sphere (having a radius of ˜20 to 25 cm). However, in many applications, a full 40 to 50 cm sphere is not required for the imaging protocol. For example, smaller imaging volumes can be used for extremity imaging (e.g., wrist). As another example, a smaller imaging volume could be defined in pediatric or infant scanning systems. Moreover, scanning can be repeated with varying acquisition FOVs to increase imaging coverage. For example, several smaller slab-like imaging volumes may be acquired while intermittently shifting the patient to a new position (e.g., along z) within the imaging FOV. The images may be stitched together during post-processing to produce images covering an overall imaging volume larger than the provided imaging FOV or prescribed acquisition FOV. In some implementations, the transverse extent (e.g., along x and y) of the imaging FOV or effective FOV may have a circular cross-section similar to that of standard imaging systems (e.g., ˜40 cm diameter). However, the axial length (e.g., along z) of the imaging FOV may be reduced (e.g., 3.5 cm).

In the present disclosure, the imaging FOV requirement is relaxed by using the less common ellipsoidal harmonics or oblate spheroidal harmonics. Use of ellipsoidal or spheroidal harmonics increases the mathematical complexity of the modeling process, which may increase computational requirements. Moreover, producing a homogeneous field constrained by an ellipsoidal FOV may increase stored energy and increase the forces applied between coil elements. However, constraining the system to an ellipsoidal FOV can advantageously facilitate a shorter and more portable magnet design. A non-spherical (or ellipsoidal) imaging FOV can allow for a reduced coil span, and thus reduced magnet opening length. Reducing the coil span can allow for a reduced cryostat bore length and, in turn, a reduced patient bore length. In one non-limiting example, fourteen electromagnetic coils arranged within a coil span of <80 cm achieve a 0.5 T main magnetic field with field homogeneity better than 10 parts per million (ppm) in an ellipsoidal imaging FOV with orthogonal axes of 35 cm, 35 cm, and 3.5 cm.

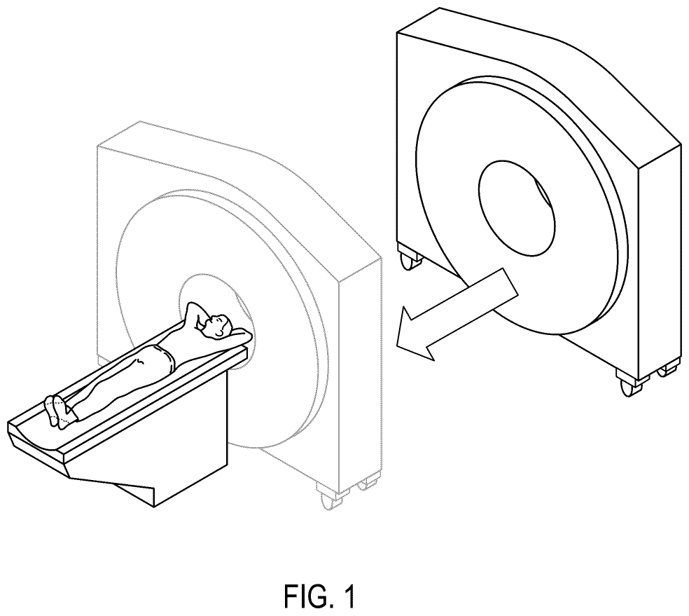

This reduction in coil span can be exploited to provide a portable MRI system, as shown in FIG. 1, for example. Such portable systems may be transferred to the patient, contrary to typical systems, which are usually located in specialized MRI suites with large footprints and high siting and maintenance costs. For example, a patient in critical condition can remain in the intensive care unit (ICU) while receiving critical imaging, or a patient can receive intraoperative imaging while remaining on the surgical table for iterative surgical approaches that increase surgical accuracy and success.

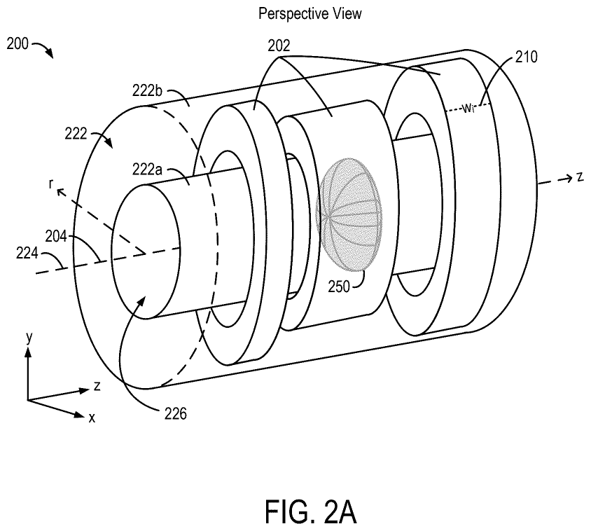

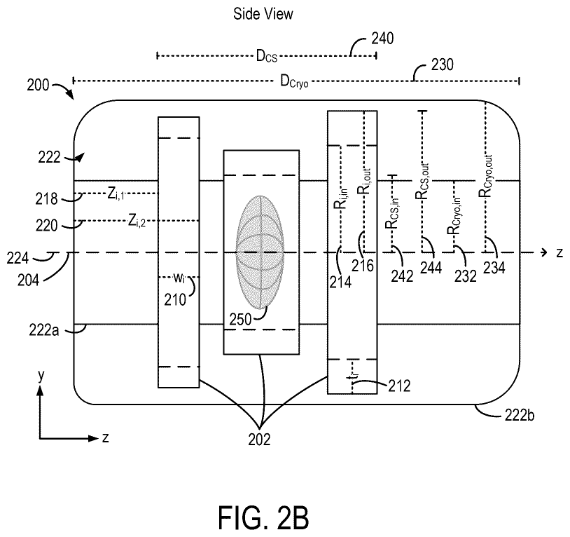

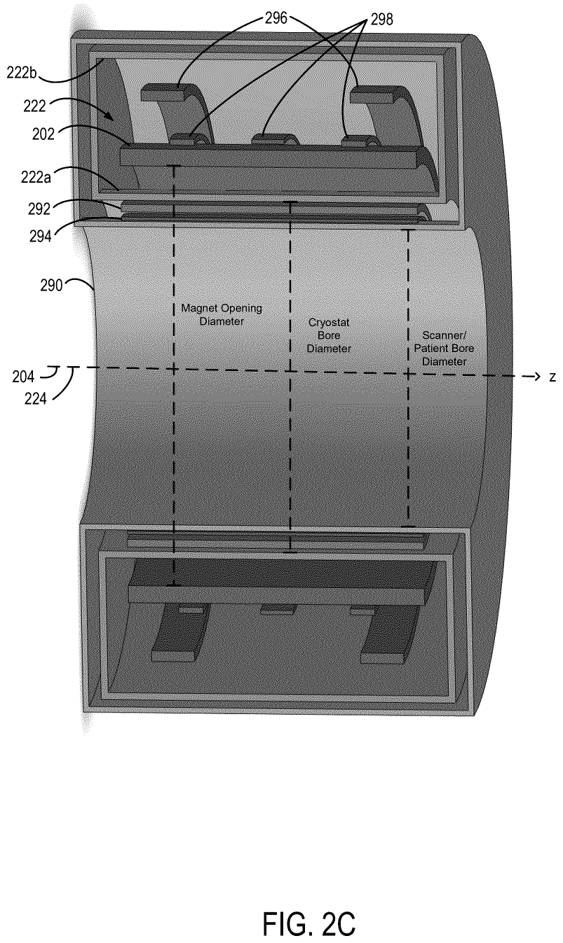

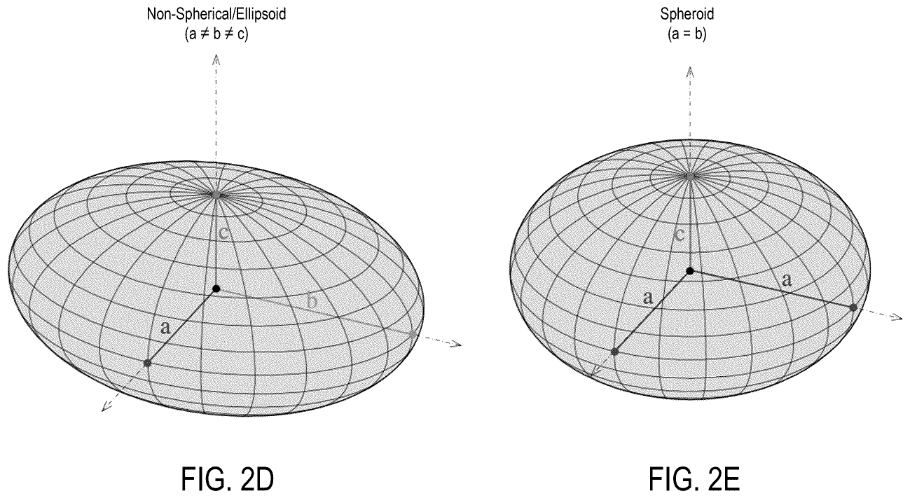

Referring now to FIGS. 2A and 2B, an example magnet system 200 is illustrated in a perspective view (FIG. 2A) and a side view (FIG. 2B). The system includes one or more electromagnetic coils 202. Such electromagnetic coils 202 are electrically conductive and configured to receive a current to produce a main magnetic field according to Faraday's law of induction. The example system 200 shown in FIGS. 2A and 2B includes three coils 202. However, any number of coils may be used. In some configurations, the coils may be configured in a symmetric pattern with respect to the x and y axes (e.g., around z=0). The number of coils 202 used may be determined based on a tradeoff between weight, size, cost, or other design constraints with the field strength, homogeneity, and imaging FOV extent that the coils 202 produce when in use. Together, the electromagnetic coils 202 form a so-called magnet opening through the center of the coil elements. The magnet opening has a center axis 204 along the z direction. The 3D extent of the electromagnetic coils 202 can be described as a coil space, where the length of the coil space is referred to as the coil span.

The electromagnetic coils 202 can be arranged within a chamber 222, which may be referred to as a cryostat. In some implementations, the chamber 222 may be a vacuum space or vacuum chamber. In some implementations, the vacuum chamber may be kept at very low temperatures (e.g., 4 K) in order to maintain superconducting properties of the coils 202 housed in the chamber. The chamber 222 may have an inner wall 222a at a radial distance R_{Cryo,in} 232 from the center axis 224 and an outer wall 222b at radial distance R_{Cryo,out} 234 from the center axis 224. The distances from the center axis 224 to the inner wall 222a and to the outer wall 222b may also be described as a function of an angle θ around the center axis 224 as r_{Cryo,in}(θ) and r_{Cryo,out}(θ), respectively. The chamber 222 may be nearly cylindrical where R_{Cryo,in} 232 and R_{Cryo,out} 234 describe average inner and outer distances (e.g., mean(r_{Cryo,in}(θ)) and mean(r_{Cryo,out}(θ))), respectively; for example, r_{Cryo,in}(θ)=[R_{Cryo,in}±0.1R_{Cryo,in}] and r_{Cryo,out}(θ)=[R_{Cryo,out}+0.1R_{Cryo,in}] for 0°≤θ<360°.

The chamber 222 can surround an inner space called a cryostat bore 226 defined by the inner wall 222a of the chamber. The cryostat bore 226 can provide space to receive a specimen to be imaged (e.g., patient) and other functional system components (e.g., gradient coils, RF coils, housing material). The cryostat bore 226 has a center axis 224 along the z direction. The center axis 224 of the cryostat bore 226 may align with the center axis 204 of the magnet opening or may not align in some implementations. The cryostat bore 226 may have a cylindrical or nearly cylindrical shape. The cryostat bore 226 may also have a cryostat bore length (D_{Cryo}) 230 that describes the length of the chamber 222 and cryostat bore 226 in the z-direction.

Electromagnetic coils 202 can be arranged within the chamber 222, the positions and size of the electromagnetic coils 202 defining a coil space that describes the 3D extent of the coil elements. The coil space can be described by a length along z (D_{CS}) 240, which may be referred to as the coil span. The coil space can further be described by an inner radius (R_{CS,in}) 242 and an outer radius (R_{CS,out}) 244. Thus, the size of the magnet opening is determined by the overall coil space. The width or diameter of the magnet opening is determined by R_{CS,in} (e.g., 2*R_{CS,in}), and the length of the magnet opening is determined by D_{CS}. In general, the size of the overall cryostat bore 226 is typically constrained by the overall coil space. For example, R_{Cryo,out}>R_{CS,out}, R_{Cryo,in}<R_{CS,in}, and D_{Cryo}>D_{CS}. Similarly, the scanner bore length and width are constrained by the length and width (e.g., 2*R_{Cryo,in}) of the cryostat bore, respectively. Thus, to increase the scanner bore's inner diameter where the patient is placed during imaging, the inner radius R_{CS,in} of the coil space must be increased. Similarly, to shorten the scanner bore length, the coil space length Des must be reduced. The magnet system can be further described based on a ratio of the magnet opening length to the magnet opening width. For example, such ratio may be defined as R_{MO}=D_{CS}/2*R_{CS,in}. The length to width ratio can be reduced by reducing the length of the coil space (e.g., D_{CS}) or increasing the width of the magnet opening.

The electromagnetic coils 202 may include superconducting coils that are kept at a low temperature (e.g., <9.4 K) to maintain superconducting properties. Each electromagnetic coil 202 can be constructed as a solenoid using an electrically conductive wire or material, such as niobium-titanium (NbTi) or niobium-tin (Nb₃Sn), which can be configured to provide low-temperature superconducting coils. The coils can also be configured as high-temperature superconducting coils using conductive materials, such as yttrium barium copper oxide (YBCO) or magnesium diboride (MgB₂). The electromagnetic coils 202 may also include non-superconducting or resistive coils. For example, non-superconducting coils can be constructed from conductive materials, such as copper or copper alloys. The electromagnetic coils 202 may also include an electrically insulating material. As a non-limiting example, the coils may be constructed from NbTi filaments or microfilaments embedded in a copper matrix. The NbTi filaments embedded in copper can form a single composite. The composite wire may be wound around to form several coil loops that make up a coil with some number of layers (e.g., along x and y) and turns (e.g., along z). Thus, the larger number of loops creates a complete solenoid coil. Each coil may also be referred to as a coil element.

Each coil 202 has a width (wᵢ) 210 along z and thickness (tᵢ) 212 along a radial direction centered at z, where i represents the i^{th} coil of N_{coil} total coils. Each coil element can be further characterized by an inner radius, R_{i,in} 214 and an outer radius, R_{i,out} 216, measured from the center of the coil element to the inner and outer surfaces of the coil element, respectively. Thus, tᵢ=R_{i,out}−R_{i,in}. The coil elements may be circular or nearly circular, in which case R_{i,in} and R_{i,out} represent an average distance from the center axis 204 to the inner or outer surface of the coil, respectively. The coil element may further be described by inner and outer radii r_{i,in}(θ) and r_{i,out}(θ) as functions of θ around the center axis 204. Nearly circular can be considered to refer to a coil element in which the distance r_{i,in}(θ) from the center axis 204 to the coil element at a position θ around the coil element is within 10% of the average distance. That is, r_{i,in}(θ)=[R_{i,in}+0.1R_{i,in}] and r_{i,out}(θ)=[R_{i,out}+0.1R_{i,out}]. The lengths of the inner radius R_{i,in} 214 and outer radius R_{i,out} 216 of each coil relate to the inner radius R_{CS,in} 242 and outer radius R_{CS,out} 244 of the overall coil space. For example,

$${R}_{C S , o u t} = {max}_{i} ( {R}_{i , o u t} ) and {R}_{C S , i n} = {min}_{i} ( {R}_{i , in} ) .$$

Each coil 202 can be placed at a position along the center axis (z) 204. The position can be described by a position of one face of the coil 202, called Z_{i,1} 218, and a position of a second face of the coil 202, called Z_{i,2} 220. That is, Z_{i,2}−Z_{i,1}=wᵢ. In some configurations, the sizes and positions of coils 202 along the z axis are symmetric with respect to the x and y axes. The position of the coils along z relates to the overall length of the coil space D_{CS} 240 or coil span. For example,

$${D}_{C S} = {max}_{i} ( {Z}_{i , 2} ) - {min}_{i} ( {Z}_{i , 1} ) ,$$

meaning that D_{CS} describes the total span of the coil elements along the z axis.

A current may be generated in each coil 202 that produces a magnetic field according to Faraday's law of induction. The current applied to each coil 202 can be described by a current density jᵢ, which has a direction within the loops. The current density jᵢ is dependent upon the winding density or cross-sectional density of electrically conductive wires within the coil, the current generated in the conductive wire loops, and the properties affecting the resistance of the coil (e.g., material used, temperature, winding length, cross-sectional area). The current density may be constrained in practice based on the maximum amount of current that can be drawn by the power source. In some implementations, the coil resistance can be eliminated by configuring the coil as a superconductor. For a superconducting coil, the current density can be described as jᵢ=Nᵢ*Iᵢ/Aᵢ, where Aᵢ is the cross-sectional area of coil i, Nᵢ is the number of wires within the cross-sectional area, and Iᵢ is the current applied to the wire in coil i. In non-superconducting coils, the current density is further dependent on the voltage applied across the coil and the resistance in the coil. Thus, the design parameters may be selected in order to achieve a desired current density jᵢ. In some implementations, the magnet system 200 may include a cryogen to cool the system and achieve superconducting properties of the coils 202. Thus, the use or omission of a cryogen may also determine or affect the maximum current density jᵢ of each coil.

As one non-limiting example, each coil may be configured with one or more particular functions. For example, the coils may be defined as primary coils, compensating coils, shielding coils, or a combination thereof. The primary coils may and be configured to add to and shape the overall magnetic field. The compensating coils may function to further shape the resulting magnetic field and to reduce the force between neighboring coils. Compensating coils may be arranged annularly outside of the primary coils. They may be configured in series with primary and shielding coils, carrying the same current as the primary coils and shielding coils. The shielding coils may function to reduce the magnetic field in the region outside of the magnet opening, a role which may be referred to as active shielding. As shown in FIG. 2C, the shielding coils 296 may be positioned radially outside the magnetic field and compensating coils 298. In some configurations, the primary coils have a positive current polarity (e.g., clockwise current), while the compensating coils have a positive or negative polarity and the shielding coils have a negative current polarity (e.g., counterclockwise current). In other configurations, the primary coils have a negative current polarity, while the compensating coils and shielding coils have a positive current polarity.

The magnet system (e.g., 200) can be used within a scanner system, as shown in FIG. 2C, for example. The scanner system can include additional components to perform imaging, spectroscopy, and so forth. For example, a housing 290 or cover can be placed around the functional components of the system. The housing 290 functions to provide a protective layer around the functional components of the magnet system 200 for convenient use. For example, the housing 290 may contain the electromagnetic coils 202, a chamber 222 (e.g., cryostat or vacuum vessel), shielding coils 296, compensating coils 298, shimming components (e.g., superconducting shimming coils, resistive shimming coils, ferromagnetic shims or ferroshims), other functional magnet components, and other system components (e.g., circuitry). In some implementations, the inner wall of the housing can receive a subject for imaging. In this way, the housing 290 can define a patient bore, which defines the space available to receive a patient or imaging specimen. Typically, the patient bore will have a smaller width than that of the cryostat bore 226. While the patient bore may be cylindrical or nearly cylindrical, it can also be another shape to surround the functional components of the magnet system 200.

The scanner system may also include gradient coils 292 and RF coils 294 that may be placed outside of the chamber 222. Such gradient coils 292 and RF coils 294 may be placed within the housing 290. They may be positioned within the cryostat bore, between the chamber inner wall 222a and the inner wall of the housing 290.

In some implementations, the scanner system may also include shimming components that are configured to further shape the main magnetic field. In some implementations, shimming components can be added to fine-tune the achieved magnetic field after the main system has been built. The shimming components can be configured based on a measured magnetic field, which may differ from the simulated field calculated in magnet design.

Shimming components can include ferromagnetic shims (e.g., iron or steel sheets or pellets) that are placed within the system (e.g., within trays annularly surrounding the scanner bore) to achieve a more uniform magnetic field. Use of ferromagnetic shims can be referred to as passive shimming. Shimming components can also include superconducting shimming coils that can be positioned within the chamber 222 or cryostat. Shimming components can also include non-superconducting or resistive shimming coils, which can be positioned outside of the chamber 222. Shimming coils may be arranged annularly inside the primary coils. Active shimming coils may be powered by a separate power source than that of the primary coils. Use of superconducting shimming coils or resistive shimming coils can be referred to as active shimming.

The coils 202 can be arranged within the magnet system 200 and configured to facilitate a current in order to produce a magnetic field within a defined imaging volume or effective FOV 250. The FOV 250 may be defined as non-spherical. In one non-limiting example, the FOV 250 may be a 3D ellipsoid. As shown in FIGS. 2D and 2E, the ellipsoid may be described by distances (a, b, and c) along three orthogonal axes (e.g., x, y, and z). In general, the FOV 250 may have relation a≠b≠c, as shown in FIG. 2D. In one non-limiting case, the ellipsoid may also be a spheroid, in which case a=b and a≠c, as shown in FIG. 2E. The ellipsoid may also be nearly (e.g., within 5% or 10%) or substantially spheroidal. For example, the nearly spheroidal ellipsoid may be described as a=[b±0.05b] or a=[b±0.1b]. The ellipsoid FOV 250 may be centered along z within the magnet opening. In some configurations, the FOV 250 may be a spheroid aligned axially within the magnet opening. That is, a=b and a>c, where a and b describe the distance along axes extending radially from the center axis of the magnet opening (e.g., x and y of the scanner bore), and c describes the distance along the center axis (z axis) of the scanner bore. As one non-limiting example, the ellipsoid FOV 250 can be described with the extent a=[35 cm±5 cm], b=[35 cm±5 cm], and c=[3.5 cm±5 cm].

The ellipsoid FOV may be further defined by ratios of a to c (Rₐ=a/c) and b to c (R_{b}=b/c). As a non-limiting example, the spheroid FOV may be described as disk-like, in which Rₐ<1 and R_{b}<1. In some configurations the disk-like FOV is much thinner in the z extent than the x and y extents. That is Rₐ<0.5 and R_{b}<0.5. In some configurations, a=b, in which case the spheroid FOV may be described by a single ratio, R=Rₐ=R_{b}, for example. As non-limiting examples, the ellipsoid FOV maybe described by Rₐ<1, Rₐ≤0.9, Rₐ≤0.8, Rₐ≤0.7, Rₐ≤0.6, Rₐ≤0.5, Rₐ≤0.4, Rₐ≤0.3, Rₐ≤0.2, Rₐ≤0.1, Rₐ≤0.05 and R_{b}<1, R_{b}≤0.9, R_{b}≤0.8, R_{b}≤0.7, R_{b}≤0.6, R_{b}≤0.5, R_{b}≤0.4, R_{b}≤0.3, R_{b}≤0.2, R_{b}≤0.1, R_{b}≤0.05. A spheroid FOV may be described by R<1, R≤0.9, R≤0.8, R≤0.7, R≤0.6, R≤0.5, R≤0.4, R≤0.3, R≤0.2, R≤0.1, R≤0.05.

In some configurations, the ellipsoid can extend transversely within the magnet opening. That is, a disk-like ellipsoid can be arranged within the magnet opening to provide a larger imaging extent in the transverse or axial plane than the imaging extent along the z axis. Put another way, a≥c and b≥c, where c extends along the center or z axis of the magnet opening, while a and b extend orthogonally along the transverse plane of the magnet opening (e.g., along x and y or y and x, respectively) or radially from the center axis.

Due to the nature of magnetic flux produced by a solenoid coil, the magnetic field produced by the magnet system 200 may not have a finite FOV extent or boundary. However, the FOV 250 may instead be defined based on a homogeneity threshold, which may be described in parts per million (ppm). For example, the homogeneity threshold may be selected as 1 ppm, 5 ppm, 10 ppm, 20 ppm, 50 ppm, 75 ppm, 100 ppm, 125 ppm, 150 ppm, 200 ppm and so on. Such homogeneity threshold refers to a homogeneity better than (e.g., less than in ppm) or equal to the threshold value. In this way, the ellipsoid FOV may refer to the largest ellipsoid in which the homogeneity level is equal or better than the homogeneity threshold. The homogeneity threshold may be selected based on a tradeoff between image quality and design constraints, such as complexity, size, cost, and others. The homogeneity threshold can also be determined based on the availability of post-processing methods. For example, the homogeneity threshold may be relaxed when used with specialized post-processing techniques that can account for field inhomogeneity.

Thus, the FOV 250 may be defined as a 3D volume in which the magnetic field produced has a homogeneity better than the homogeneity threshold. This FOV 250 can define an imaging extent in which the magnetic field is sufficiently homogeneous to produce images of sufficient quality. The extent of the FOV 250 described by distances a, b, and c, can be determined based on the application and a tradeoff between homogeneity and system complexity or other design constraints.

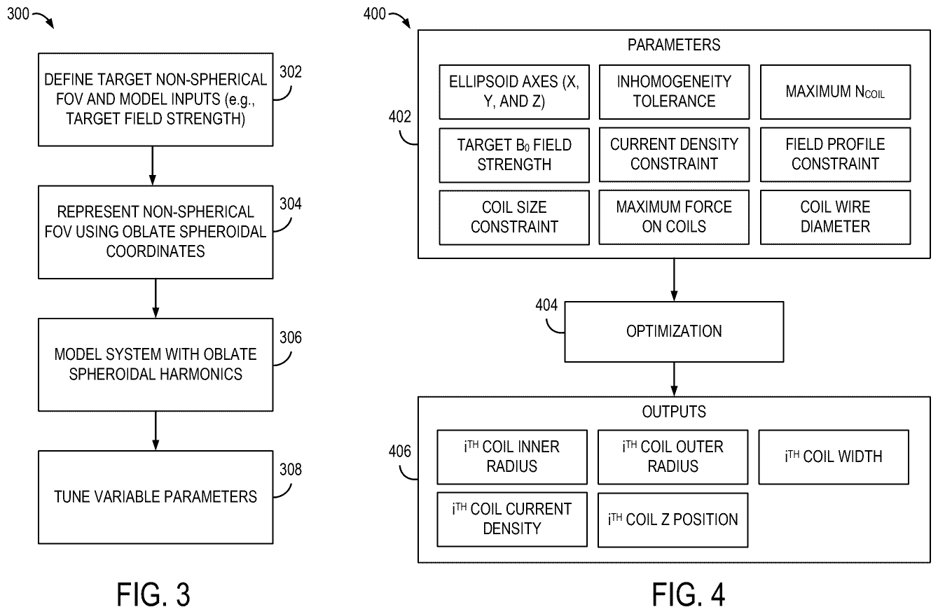

Referring to FIG. 3, a flowchart is provided that illustrates an example process 300 for designing a magnet system (e.g., 200). In general, the process 300 can be used to determine the coil parameters of each of the coils that can produce a magnetic field of a desired strength and homogeneity within a desired or target FOV. In this way, process 300 can include determining the configuration of primary coils, compensating coils, shielding coils, or a combination thereof. For example, parameters of primary coils, compensating coils, and shielding coils can be determined in process 300 to shape a sufficiently homogeneous field, while reducing a fringe field and forces between coils. The coil parameters may include size (e.g., wᵢ 210, R_{i,in} 214, and R_{i,out} 216), position (e.g., z_{i,1} 218 and z_{i,2} 220), current density, or some combination thereof.

In block 302, a target FOV can be defined. The target FOV may be described in part by a position within the magnet opening. For example, the position of the target FOV may be described based on the center of a non-spherical target FOV positioned with respect to the magnet opening (e.g., centered within the magnet opening). The non-spherical target FOV may further be defined as a spheroid or general ellipsoid. Defining the ellipsoid target FOV may also include defining the distances a, b, and c based on a desired extent of the target FOV, which may depend on the application. Other model inputs may also be defined in block 302. For example, the model inputs may include a target field strength, which may be referred to as B₀, a homogeneity threshold, target field profile, and design constraints. For example, the target field strength may be defined for low field imaging (e.g., 0.1 T, 0.2 T, 0.25 T, 0.3 T, 0.5 T, 0.6 T), conventional field imaging (e.g., 1 T, 1.5 T), high field imaging (2 T, 3 T, 4 T, 5 T, 6 T), or ultra-high field (7 T, 8 T, 10.5 T, 11 T, and so on). The field homogeneity threshold may be determined based on the application and available post-processing methods for field correction. The field homogeneity can be described in ppm within the defined target FOV or other desired imaging region. The target field profile may include a limit on the fringe field, which describes the strength of the magnetic field outside of the magnet opening. As a non-limiting example, the field profile constraint may require the magnetic field to be <5 gauss for distances >1 meter from the magnet opening.

The design constraints can be determined based on desired cost, size, power, and portability constraints. For example, the minimum inner radius of each coil may be determined to accommodate the size of a desired patient population (e.g., infants, pediatrics, adults) or imaging application (e.g., brain imaging, torso imaging, extremity imaging, intraoperative imaging). The outer radius and width of each coil may be constrained by a maximum desired system size or weight (e.g., to fit through a doorway, to be easily portable on wheels). As non-limiting examples, the overall system weight can be constrained to <5000 lbs., <4000 lbs., <3500 lbs., <3000 lbs., <2500 lbs., <2000 lbs., <1500 lbs., or <1000 lbs. In some configurations, the overall system weight may be configured as 1000-2000 lbs., 2000-3000 lbs., 3000-3500 lbs., or 3500-4500 lbs. The maximum current density may be defined based on power access (e.g., 120 V or 240 V outlet or power supply), material cost, ability to cool the system (e.g., cost of and access to cryogen or other cooling mechanism), or ability to achieve superconducting properties. Constraints may also be defined for model or design simplicity (e.g., jᵢϵ[−218.75, 218.75], predefined number of coils, predefined coil sizes). Design constraints may also include other safety- or practicality-related constraints. For example, a constraint may be set to limit the total force that will be applied between neighboring coils. As other non-limiting examples, design constraints can also include space limitations, peak magnetic fields produced by each coil, thermal considerations, wire properties and availability, and power supply properties and availability. While several example design constraints and considerations are provided herein, other design constraints may be defined based on the desired application and available resources.

In block 304, a model of a non-spherical target FOV can be generated by representing the target FOV using oblate spheroidal coordinates. Modeling the target FOV may include deriving an analytical form for the general fields in the non-spherical or ellipsoidal region of interest in terms of oblate spheroidal coordinates. In some configurations, the magnetic flux is simulated or calculated along the surface of the ellipsoidal region of interest based on the size and shape of the target FOV, current density of each coil, location of each coil, wire diameters, and spatial arrangement of wires within each coil. In some implementations, the field is modeled outside of the target FOV. For example, the magnetic field may be calculated at several points some distance away from the ellipsoidal FOV to maintain constraints on the fringe field.

The magnet system can be modeled in block 306 using oblate spheroidal harmonics. To model the magnet system, the magnetic field generated by the external coils is calculated or estimated. For example, the magnetic flux can be modeled across the boundary of the FOV. In the model, each electromagnetic coil can be represented by a single infinitesimally small wire loop or a large number of circular wire loops. In some implementations, the system model may include a model of the current flowing through a cross-sectional area of each individual coil element. In some implementations, the model may include a current flowing through each individual wire or wire loop. In some configurations, the form of the model can change throughout the tuning process.

In some implementations, the magnetic flux can be modeled based on a theoretical description of tunable currents placed in space. That is, theoretical currents can be placed in space in order to produce a magnetic flux of sufficient homogeneity and strength within the desired FOV. In this way, the radial position and position along z (Z_{i,1}) can be tuned for each current. Thus, the coil elements can be considered to generate a tuned current despite having infinitesimal widths and thicknesses.

In subsequent steps, physical coil elements with tunable current densities can be modeled to generate the tuned, spatially distributed currents. In some implementations, modeling the physical coil elements may include modeling each individual coil loop within the coil element. As a non-limiting example, the wire diameter can be predefined in order to determine the proper size of each coil element that will produce the desired distribution of current density. Thus, the coil element sizes can be determined by tuning R_{i,in}, R_{i,out}, and wᵢ to distribute jᵢ throughout each coil element (e.g., from Z_{i,1} to Zₑ and R_{i,in} to R_{i,out}) at Z_{i,1} based on a wire diameter of each loop within the coil elements. In some implementations, expanding the model to consider physical coil elements may alter or reduce the simulated field (e.g., homogeneity) compared to the field modeled based on theoretical current densities. Thus, the modeling process may include iterative steps. For example, the positions (Z_{i,1}) of the coils can be adjusted or tuned to restore the desired field.

In some implementations the current density may be predefined by a given value with positive or negative polarity or current direction. The total number of coils N_{coil} may be pre-defined or variable.

Using the system model, the variable parameters can be tuned in block 308. Tuning the system includes modifying independent variable parameters to achieve a desired outcome while maintaining desired constraints. In some implementations, tuning the system may include increasing a dependent variable parameter, such as field homogeneity modeled within the defined target FOV based on the calculated magnetic field, to achieve a desired outcome. Other dependent parameters that may be increased or optimized include overall field strength and inner magnet opening radius. In other implementations, tuning the system may include decreasing dependent variable parameters, such as system size, weight, number of coils, current density, power requirement, and so on. In this way, the dependent variable parameters, which may be constrained, may be interchanged for the predefined or independent variable parameters based on the desired or prioritized outcome. In one example, tuning the parameters includes determining an optimal or nearly optimal position and current density direction of each of the N_{coil} coils in order to increase field homogeneity within the target FOV. The positions and current densities can further be used to determine positions and sizes of physical coil elements.

In some implementations, the modeling process can further include tuning or determining placements and current densities of shimming coils. Such shimming coils may be used to shape the magnetic field to increase field homogeneity. As a non-limiting example, placement and current densities of shim coils can be determined as similarly described above in the context of primary coils. As another example, placement or current densities of shim coils can be iteratively determined after measuring the realized field produced by the physical system. In some implementations, configuring shimming coils can include both theoretical modeling and experimental adjustments of the shim coils. For example, the current densities and initial positions can be determined by the model, and the final placement of each coil can be adjusted after measuring the field produced by the physical system.

FIG. 4 illustrates an example tuning process 400 in greater detail. Several example input parameters 402 and output parameters 406 are illustrated for example purposes. However, as previously described the input and output parameters may be interchangeable based on the desired system outcome (e.g., to prioritize portability over homogeneity). As one non-limiting example, while target B₀ field strength is illustrated as an input parameter, the optimization or tuning 404 may be performed to increase B₀ field strength such that the achieved B₀ field strength serves as a model output. In this case, the B₀ field may be constrained as an input parameter, if desired.

A magnet system can be built according to the tuning 404 and output parameters 406. Such magnet system may produce an effective FOV that may be different than the target FOV. For example, the effective FOV may have a region of sufficient homogeneity that extends beyond the pre-defined target FOV. Thus, in practice, the acquisition FOV may be defined based on the resulting or effective FOV rather than the target FOV.

### EXAMPLES

### Example 1

As a non-limiting example, the system can be described as having R_{MO}≤1.2 with a field strength of at least 250 mT with homogeneity of 100 ppm or better over an ellipsoid FOV with a=[35 cm±5 cm], b=[35 cm±5 cm], and c=[3.5 cm±5 cm]. As another non-limiting example, the system can be described as having D_{CS}≤100 cm and R_{CS,in}≤40 cm with a field strength of at least 250 mT with homogeneity of 100 ppm or better over an ellipsoid FOV with a=[35 cm±5 cm], b=[35 cm±5 cm], and c=[3.5 cm±5 cm]. As another non-limiting example, the system can be described as having D_{CS}≤80 cm and R_{CS,in}≤40 cm with a field strength of at least 250 mT with homogeneity of 100 ppm or better over an ellipsoid FOV with a=[35 cm±5 cm], b=[35 cm±5 cm], and c=[3.5 cm±5 cm].

### Example 2

As a non-limiting example, the positions and current density directions of 14 coils were optimized or tuned to increase homogeneity within an ellipsoid FOV. The ellipsoid was defined as a spheroid with a sagittal and coronal length of 35 cm (a=b=35 cm) and an axial or transverse length of 3.5 cm (c=3.5 cm). The static field strength was defined as 0.5 T. The wire diameter was predefined based on iterative experimentation. The tuned position and current density of each coil is listed in Table I below. Table I provides the positions and current densities of seven of the 14 coils, the other seven coils are placed symmetrically along the z-axis or across the center transverse plane. Once the positions and current densities are determined for each coil, individual coil elements were modeled to determine the inner radius, outer radius, and width of each coil that produces the desired current density, as shown in Table I. Based on the model results, such system design can achieve a 0.5 T magnetic field within the ellipsoid FOV with better than 10 ppm homogeneity and a magnet opening length or coil span of <80 cm. Such a set of coils is suitable to provide a wide-bore class MRI superconducting magnet.

TABLE I

| | Inputs | | | Outputs | | |
|---|---|---|---|---|---|---|
| | Inner | Outer | | Inner Z | Outer Z | Current |
| Coil | Radius | Radius | Width | Limit | Limit | Density |
| # | (R_{i, in}) | (R_{i, out}) | (wᵢ) | (Z_{i, 1}) | (Z_{i, 2}) | (Jᵢ) |
| 1 | 49.1 cm | 51.0 cm | 4.7 cm | 0.03 cm | 4.8 cm | −218.75 A/m² |
| 2 | 48.4 cm | 51.6 cm | 7.9 cm | 6.1 cm | 13.9 cm | 218.75 A/m² |
| 3 | 48.7 cm | 51.3 cm | 6.4 cm | 15.8 cm | 22.2 cm | −218.75 A/m² |
| 4 | 49.4 cm | 50.6 cm | 2.8 cm | 25.6 cm | 28.4 cm | −218.75 A/m² |
| 5 | 50.47 cm | 53.6 cm | 8.2 cm | 29.5 cm | 37.7 cm | 218.75 A/m² |
| 6 | 76.9 cm | 79.1 cm | 5.6 cm | 23.2 cm | 28.8 cm | −218.75 A/m² |
| 7 | 77.5 cm | 78.5 cm | 2.5 cm | 6.7 cm | 9.3 cm | 218.75 A/m² |

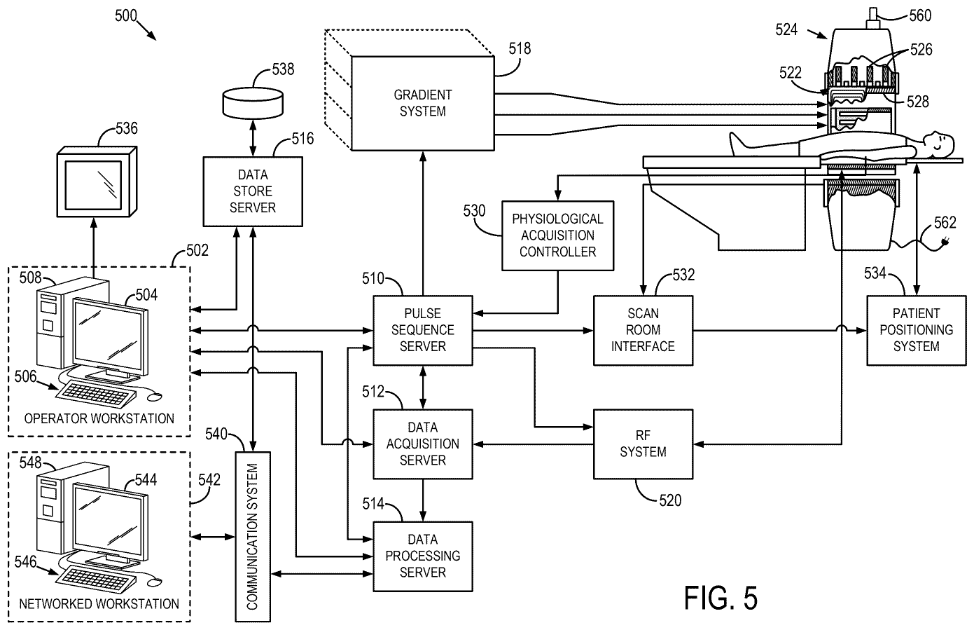

Referring particularly now to FIG. 5, an example of an MRI system 500 that can implement the methods described herein is illustrated. The MRI system 500 includes an operator workstation 502 that may include a display 504, one or more input devices 506 (e.g., a keyboard, a mouse), and a processor 508. The processor 508 may include a commercially available programmable machine running a commercially available operating system. The operator workstation 502 provides an operator interface that facilitates entry of scan parameters into the MRI system 500. The operator workstation 502 may be coupled to different servers, including, for example, a pulse sequence server 510, a data acquisition server 512, a data processing server 514, and a data store server 516. The operator workstation 502 and the servers 510, 512, 514, and 516 may be connected via a communication system 540, which may include wired or wireless network connections.

The MRI system 500 also includes a short-bore magnet assembly 524 that includes magnet components 526, which may be a low-field magnet. As previously described, the magnet components 526 may be configured to produce a static magnetic field within a non-spherical or an ellipsoid FOV. The MRI system 500 may optionally include a whole-body RF coil 528 and a gradient system 518 that controls a gradient coil assembly 522. The short-bore magnet assembly 524 may optionally include a cryogen and cold head or cooling system 560, which may cool the system to achieve super-conducting properties in the magnet components 526. The magnet assembly 524 may also include a power source 562, which may include a power cord compatible with a standard power outlet.

In some implementations, the magnet assembly 524 may produce a static magnetic field that remains “on” indefinitely, as standard MRI systems do. In other implementations the magnet assembly 524 may be configured to quickly ramp up to the desired field strength when in use and ramp down to no or low field when not in use. In this way, the power supply and cryogen and cold head or other cooling system may be temporarily accessible. For example, the system may be rolled into a room, plugged into a power outlet to provide a power source 562, and connected to a cooling unit or cooling system 560 (e.g., a cryocooler). The system can then be ramped up to field for imaging. After imaging, the system can be disconnected, ramped down, and wheeled to another patient room, to storage, or to other desired location.

In other implementations, the system can be stored in an un-charged state while connected to a cooling system. For example, the cooling system may include a cryogen (e.g., liquid helium or another refrigerant). Such cooling system can be used to maintain the magnet elements at an operating temperature (e.g., superconducting temperature). When the system is needed for scanning, it can be disconnected from the cooling system and transported to the patient or scan room where it can be connected to a power source. The power source can provide a voltage that creates a current to flow across the cooled magnet elements. In some configurations, the cooled magnet elements can be insulated (e.g., via a vacuum vessel) such that they maintain a sufficiently cold temperature for a sufficient length of time without being actively cooled or being coupled to a cooling system. The sufficient length of time may be determined by the scan time needed for a patient exam. The sufficiently cold temperature may be determined based on the temperature required to maintain superconducting properties of the coil or based on the temperature required to produce a desired magnetic field (e.g., strength and homogeneity). In this way, the scanner system can remain at an operable temperature throughout the length of the scan (e.g., up to 2 hours) while in use. After scanning, the system can be discharged or ramped down and returned to storage where it is can be re-coupled to the cooling system.

In other implementations, the system can be transported between several cooling systems. For example, the system can be stored in a storage area (e.g., storage room) while connected to a storage cooling system. Such system can maintain the magnet system at a sufficiently low temperature (e.g., to maintain superconducting properties of the conductors). To use the system, it can be disconnected from the cooling system and transported into a scan room or to a patient (e.g., to the ICU) and connected to a second cooling system. This second cooling system may be referred to as a scanning cooling system. Such cooling system can again maintain superconducting properties of the magnet while the system is in use. In this way, the insulation requirements of the magnet elements may be relaxed, as the time that the system is disconnected from a cooling system can be reduced or minimized (e.g., the short time it takes to roll the system through the hospital from storage to a patient, from a patient to storage, or from one patient to another patient). In some configurations, the scanning cooling system may have relaxed cooling requirements compared to that of the storage cooling system or vice versa. For example, the storage cooling system may be sufficient to cool the magnet elements from room temperature to superconducting temperatures while the scanning cooling system may be sufficient to maintain superconducting temperatures during scanning.

In other implementations, the magnet system can include a non-superconducting or resistive magnet. Thus, a cooling system may not be required.

The pulse sequence server 510 functions in response to instructions provided by the operator workstation 502 to operate a gradient system 518 and a radiofrequency (“RF”) system 520. Gradient waveforms for performing a prescribed scan are produced and applied to the gradient system 518, which then excite gradient coils in an assembly 522 to produce the magnetic field gradients (e.g., Gₓ, G_{y}, and G_{z}) that can be used for spatially encoding magnetic resonance signals. The gradient coil assembly 522 forms part of a magnet assembly 524 that includes magnet components 526 and a whole-body RF coil 528.

RF waveforms are applied by the RF system 520 to the RF coil 528, or a separate local coil to perform the prescribed magnetic resonance pulse sequence. Responsive magnetic resonance signals detected by the RF coil 528, or a separate local coil, are received by the RF system 520. The responsive magnetic resonance signals may be amplified, demodulated, filtered, and digitized under direction of commands produced by the pulse sequence server 510. The RF system 520 includes an RF transmitter for producing a wide variety of RF pulses used in MRI pulse sequences. The RF transmitter is responsive to the prescribed scan and direction from the pulse sequence server 510 to produce RF pulses of the desired frequency, phase, and pulse amplitude waveform. The generated RF pulses may be applied to the whole-body RF coil 528 or to one or more local coils or coil arrays.

The RF system 520 also includes one or more RF receiver channels. An RF receiver channel includes an RF preamplifier that amplifies the magnetic resonance signal received by the coil 528 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{( {I}^{2} + {Q}^{2} )}$$

and the phase of the received magnetic resonance signal may also be determined according to the following relationship:

$$ϕ = {tan}^{- 1} ( \frac{Q}{I} )$$

The pulse sequence server 510 may receive patient data from a physiological acquisition controller 530. By way of example, the physiological acquisition controller 530 may receive signals from a number of different sensors connected to the patient, including electrocardiogramals from electrodes, or respiratory signals from a respiratory bellows or other respiratory monitoring devices. These signals may be used by the pulse sequence server 510 to synchronize, or “gate,” the performance of the scan with the subject's heartbeat or respiration.

The pulse sequence server 510 may also connect to a scan room interface circuit 532 that receives signals from various sensors associated with the condition of the patient and the magnet system. Through the scan room interface circuit 532, a patient positioning system 534 can receive commands to move the patient to desired positions during the scan.

The digitized magnetic resonance signal samples produced by the RF system 520 are received by the data acquisition server 512. The data acquisition server 512 operates in response to instructions downloaded from the operator workstation 502 to receive the real-time magnetic resonance data and provide buffer storage, so that data are not lost by data overrun. In some scans, the data acquisition server 512 passes the acquired magnetic resonance data to the data processor server 514. In scans that require information derived from acquired magnetic resonance data to control the further performance of the scan, the data acquisition server 512 may be programmed to produce such information and convey it to the pulse sequence server 510. For example, during pre-scans, magnetic resonance data may be acquired and used to calibrate the pulse sequence performed by the pulse sequence server 510. As another example, navigator signals may be acquired and used to adjust the operating parameters of the RF system 520 or the gradient system 518, or to control the view order in which k-space is sampled. In still another example, the data acquisition server 512 may also process magnetic resonance signals used to detect the arrival of a contrast agent in a magnetic resonance angiography (“MRA”) scan. For example, the data acquisition server 512 may acquire magnetic resonance data and processes it in real-time to produce information that is used to control the scan.

The data processing server 514 receives magnetic resonance data from the data acquisition server 512 and processes the magnetic resonance data in accordance with instructions provided by the operator workstation 502. Such processing may include, for example, reconstructing two-dimensional or three-dimensional images by performing a Fourier transformation of raw k-space data, performing other image reconstruction algorithms (e.g., iterative or back-projection reconstruction algorithms), applying filters to raw k-space data or to reconstructed images, generating functional magnetic resonance images, or calculating motion or flow images.

Images reconstructed by the data processing server 514 are conveyed back to the operator workstation 502 for storage. Real-time images may be stored in a data base memory cache, from which they may be output to operator display 502 or a display 536. Batch mode images or selected real time images may be stored in a host database on disc storage 538. When such images have been reconstructed and transferred to storage, the data processing server 514 may notify the data store server 516 on the operator workstation 502. The operator workstation 502 may be used by an operator to archive the images, produce films, or send the images via a network to other facilities.

The MRI system 500 may also include one or more networked workstations 542. For example, a networked workstation 542 may include a display 544, one or more input devices 546 (e.g., a keyboard, a mouse), and a processor 548. The networked workstation 542 may be located within the same facility as the operator workstation 502, or in a different facility, such as a different healthcare institution or clinic.

The networked workstation 542 may gain remote access to the data processing server 514 or data store server 516 via the communication system 540. Accordingly, multiple networked workstations 542 may have access to the data processing server 514 and the data store server 516. In this manner, magnetic resonance data, reconstructed images, or other data may be exchanged between the data processing server 514 or the data store server 516 and the networked workstations 542, such that the data or images may be remotely processed by a networked workstation 542.

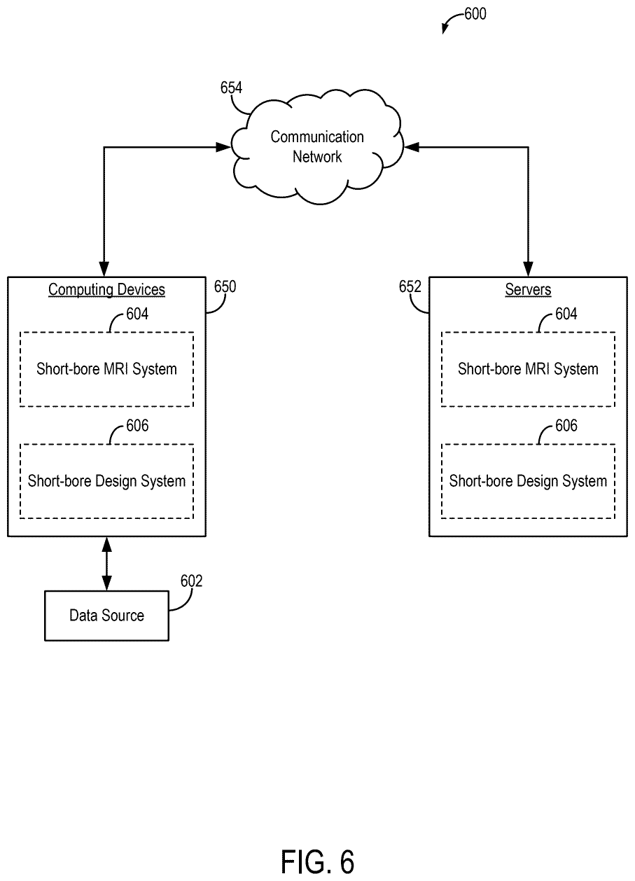

Referring now to FIG. 6, an example of a system 600 is shown, which may be used in accordance with some aspects of the systems and methods described in the present disclosure. As shown in FIG. 6, computing devices 650 can receive one or more types of data (e.g., signal evolution data, k-space data, receiver coil sensitivity data) from data source 602. In some configurations, the computing devices 650 can execute at least a portion of a short-bore MRI system 604 to reconstruct images from magnetic resonance data (e.g., k-space data) acquired using standard methods. In some configurations, the short-bore MRI system 604 can implement an automated pipeline to provide MRI images of a non-spherical or an ellipsoid FOV. In some configurations, the computing devices 650 can execute at least a portion of a short-bore design system 606 to tune design parameters of a magnet system (e.g., as in FIGS. 3 and 4).

Additionally or alternatively, in some configurations, the computing devices 650 can communicate information about data received from the data source 602 to server(s) 652 over a communication network 654, which can execute at least a portion of the short-bore MRI system 604 and/or short-bore design system 606. In such configurations, the server(s) 652 can return information to the computing devices 650 (and/or any other suitable computing device) indicative of an output of the short-bore MRI system 604 and/or short-bore design system 606.

In some configurations, computing devices 650 and/or server(s) 652 can be any suitable computing device or combination of devices, such as a desktop computer, a laptop computer, a smartphone, a tablet computer, a wearable computer, a server computer, a virtual machine being executed by a physical computing device, and so on. The computing devices 650 and/or server(s) 652 can also reconstruct images from the data.

In some configurations, data source 602 can be any suitable source of data (e.g., measurement data, images reconstructed from measurement data, processed image data), such as an MRI system, another computing device (e.g., a server storing measurement data, images reconstructed from measurement data, processed image data), and so on. In some configurations, data source 602 can be local to computing devices 650. For example, data source 602 can be incorporated with computing devices 650 (e.g., computing devices 650 can be configured as part of a device for measuring, recording, estimating, acquiring, or otherwise collecting or storing data). As another example, data source 602 can be connected to computing devices 650 by a cable, a direct wireless link, and so on. Additionally or alternatively, in some configurations, data source 602 can be located locally and/or remotely from computing devices 650, and can communicate data to computing devices 650 (and/or server(s) 652) via a communication network (e.g., communication network 654).

In some configurations, communication network 654 can be any suitable communication network or combination of communication networks. For example, communication network 654 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some configurations, communication network 654 can be a local area network, a wide area network, a public network (e.g., the Internet), a private or semi-private network (e.g., a corporate or university intranet), any other suitable type of network, or any suitable combination of networks. Communications links shown in FIG. 6 can each be any suitable communications link or combination of communications links, such as wired links, fiber optic links, Wi-Fi links, Bluetooth links, cellular links, and so on.

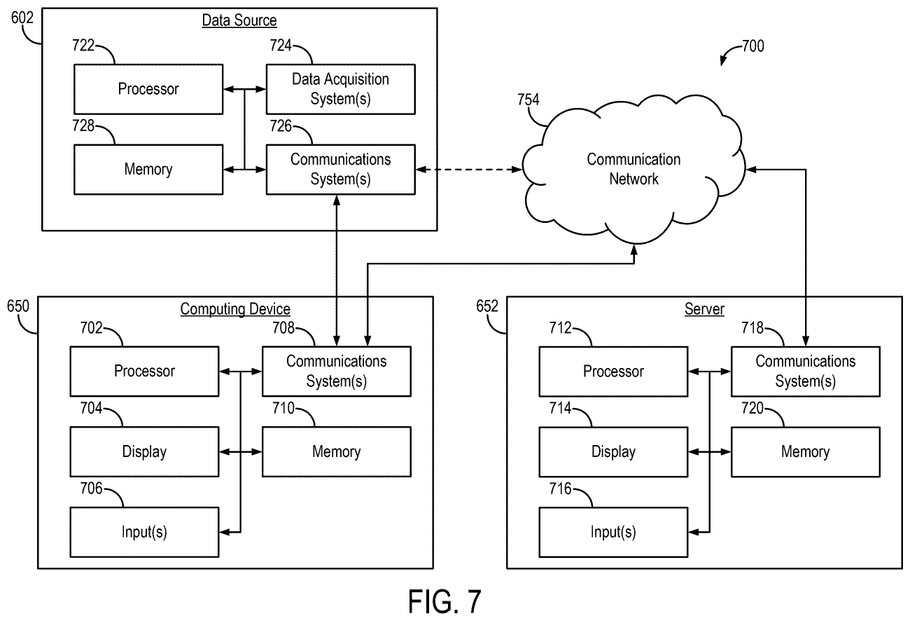

Referring now to FIG. 7, an example of hardware 700 that can be used to implement data source 602, computing devices 650, and server(s) 652 in accordance with some configurations of the systems and methods described in the present disclosure is shown.

As shown in FIG. 7, in some configurations, computing devices 650 can include a processor 702, a display 704, one or more inputs 706, one or more communication systems 708, and/or memory 710. In some configurations, processor 702 can be any suitable hardware processor or combination of processors, such as a central processing unit (“CPU”), a graphics processing unit (“GPU”), and so on. In some configurations, display 704 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some configurations, inputs 706 can include any suitable input devices and/or sensors that can be used to receive user input, such as a keyboard, a mouse, a touchscreen, a microphone, and so on.

In some configurations, communications systems 708 can include any suitable hardware, firmware, and/or software for communicating information over communication network 654 and/or any other suitable communication networks. For example, communications systems 708 can include one or more transceivers, one or more communication chips and/or chip sets, and so on. In a more particular example, communications systems 708 can include hardware, firmware, and/or software that can be used to establish a Wi-Fi connection, a Bluetooth connection, a cellular connection, an Ethernet connection, and so on.

In some configurations, memory 710 can include any suitable storage device or devices that can be used to store instructions, values, data, or the like, that can be used, for example, by processor 702 to present content using display 704, to communicate with server(s) 652 via communications system(s) 708, and so on. Memory 710 can include any suitable volatile memory, non-volatile memory, storage, or any suitable combination thereof. For example, memory 710 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some configurations, memory 710 can have encoded thereon, or otherwise stored therein, a computer program for controlling operation of computing devices 650. In such configurations, processor 702 can execute at least a portion of the computer program to present content (e.g., images, user interfaces, graphics, tables), receive content from server(s) 652, transmit information to server(s) 652, and so on. For example, the processor 702 and the memory 710 can be configured to perform the methods described herein.

In some configurations, server(s) 652 can include a processor 712, a display 714, one or more inputs 716, one or more communications systems 718, and/or memory 720. In some configurations, processor 712 can be any suitable hardware processor or combination of processors, such as a CPU, a GPU, and so on. In some configurations, display 714 can include any suitable display devices, such as an LCD screen, LED display, OLED display, electrophoretic display, a computer monitor, a touchscreen, a television, and so on. In some configurations, inputs 716 can include any suitable input devices and/or sensors that can be used to receive user input, such as a keyboard, a mouse, a touchscreen, a microphone, and so on.

In some configurations, communications systems 718 can include any suitable hardware, firmware, and/or software for communicating information over communication network 654 and/or any other suitable communication networks. For example, communications systems 718 can include one or more transceivers, one or more communication chips and/or chip sets, and so on. In a more particular example, communications systems 718 can include hardware, firmware, and/or software that can be used to establish a Wi-Fi connection, a Bluetooth connection, a cellular connection, an Ethernet connection, and so on.

In some configurations, memory 720 can include any suitable storage device or devices that can be used to store instructions, values, data, or the like, that can be used, for example, by processor 712 to present content using display 714, to communicate with one or more computing devices 650, and so on. Memory 720 can include any suitable volatile memory, non-volatile memory, storage, or any suitable combination thereof. For example, memory 720 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some configurations, memory 720 can have encoded thereon a server program for controlling operation of server(s) 652. In such configurations, processor 712 can execute at least a portion of the server program to transmit information and/or content (e.g., data, images, a user interface) to one or more computing devices 650, receive information and/or content from one or more computing devices 650, receive instructions from one or more devices (e.g., a personal computer, a laptop computer, a tablet computer, a smartphone), and so on.

In some configurations, the server(s) 652 is configured to perform the methods described in the present disclosure. For example, the processor 712 and memory 720 can be configured to perform the methods described herein.

In some configurations, data source 602 can include a processor 722, one or more data acquisition systems 724, one or more communications systems 726, and/or memory 728. In some configurations, processor 722 can be any suitable hardware processor or combination of processors, such as a CPU, a GPU, and so on. In some configurations, the one or more data acquisition systems 724 are generally configured to acquire data, images, or both, and can include an MRI system. Additionally or alternatively, in some configurations, the one or more data acquisition systems 724 can include any suitable hardware, firmware, and/or software for coupling to and/or controlling operations of an MRI system. In some configurations, one or more portions of the data acquisition system(s) 724 can be removable and/or replaceable.

Note that, although not shown, data source 602 can include any suitable inputs and/or outputs. For example, data source 602 can include input devices and/or sensors that can be used to receive user input, such as a keyboard, a mouse, a touchscreen, a microphone, a trackpad, a trackball, and so on. As another example, data source 602 can include any suitable display devices, such as an LCD screen, an LED display, an OLED display, an electrophoretic display, a computer monitor, a touchscreen, a television, etc., one or more speakers, and so on.

In some configurations, communications systems 726 can include any suitable hardware, firmware, and/or software for communicating information to computing devices 650 (and, in some configurations, over communication network 654 and/or any other suitable communication networks). For example, communications systems 726 can include one or more transceivers, one or more communication chips and/or chip sets, and so on. In a more particular example, communications systems 726 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some configurations, memory 728 can include any suitable storage device or devices that can be used to store instructions, values, data, or the like, that can be used, for example, by processor 722 to control the one or more data acquisition systems 724, and/or receive data from the one or more data acquisition systems 724; to generate images from data; present content (e.g., data, images, a user interface) using a display; communicate with one or more computing devices 650; and so on. Memory 728 can include any suitable volatile memory, non-volatile memory, storage, or any suitable combination thereof. For example, memory 728 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some configurations, memory 728 can have encoded thereon, or otherwise stored therein, a program for controlling operation of medical image data source 602. In such configurations, processor 722 can execute at least a portion of the program to generate images, transmit information and/or content (e.g., data, images, a user interface) to one or more computing devices 650, receive information and/or content from one or more computing devices 650, receive instructions from one or more devices (e.g., a personal computer, a laptop computer, a tablet computer, a smartphone, etc.), and so on.

In some configurations, any suitable computer-readable media can be used for storing instructions for performing the functions and/or processes described herein. For example, in some configurations, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As used herein in the context of computer implementation, unless otherwise specified or limited, the terms “component,” “system,” “module,” “controller,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

As used herein, the phrase “at least one of A, B, and C” means at least one of A, at least one of B, and/or at least one of C, or any one of A, B, or C or combination of A, B, or C. A, B, and C are elements of a list, and A, B, and C may be anything contained in the Specification.

The present disclosure has described one or more preferred embodiments, and it should be appreciated that many equivalents, alternatives, variations, and modifications, aside from those expressly stated, are possible and within the scope of the invention.

1. A magnetic resonance imaging (MRI) system comprising:
a magnet opening having a ratio of an opening length over an opening diameter, the ratio being smaller than 1.2; and
a plurality of electromagnetic coils configured to generate a static magnetic field within a field of view (FOV), wherein the FOV is a non-spherical shape, and wherein the static magnetic field within the FOV has a measure of homogeneity better than 100 parts per million.

2. The MRI system of claim 1, wherein the magnet opening has a length of less than 100 cm.

3. The MRI system of claim 1, further comprising a cryostat that contains the plurality of electromagnetic coils, the cryostat having an inner wall that defines a cryostat bore.

4. The MRI system of claim 1, wherein the non-spherical shape is an ellipsoid extending with a maximum radius aligned transversely to a length of the magnet opening.

5. The MRI system of claim 1, wherein the magnet opening is cylindrical.

6. The MRI system of claim 1, wherein each of the plurality of electromagnetic coils has an inner radius, an outer radius, a width, and a current density, and wherein the magnet opening has a center axis and each of the plurality of electromagnetic coils is characterized by a position along the center axis.

7. The MRI system of claim 1, wherein the static magnetic field has a field strength of at least 250 mT within the field of view.

8. The MRI system of claim 5, wherein the minimum inner radius of each of the plurality of electromagnetic coils is at least 40 cm.

9. The MRI system of claim 5, wherein the cylindrical opening has a maximum length of 80 cm.

10. The MRI system of claim 1, wherein the MRI system is portable.

11. The MRI system of claim 1, wherein the non-spherical FOV is an ellipsoid characterized by orthogonal axes a, b, and c, wherein axes a and b extend radially from a center axis of the magnet opening and axis c extends long the center axis of the magnet opening.

12. The MRI system of claim 11, wherein the ellipsoid is a spheroid characterized by a=b and b≠c.

13. The MRI system of claim 12, wherein a=[35 cm±5 cm], b=[35 cm±5 cm], and c=[3.5 cm±5 cm].

14. A method for producing a static magnetic field, wherein the method comprises using a computer system to:
define an imaging field of view with a non-spherical shape;
define a target static field strength;
calculate a field produced by a plurality of electromagnetic coils, wherein each of the plurality of electromagnetic coils has a current, a width, a position, an inner radius, and an outer radius; and
reduce an inhomogeneity of the calculated field by adjusting at least one of the current, width, position, inner radius, or outer radius of each of the plurality of electromagnetic coils.

15. The method of claim 14, wherein the non-spherical shape is an ellipsoid.

16. The method of claim 14, wherein defining an imaging field of view with a non-spherical shape comprises generating an analytical representation the imaging field of view in oblate spheroidal coordinates.

17. The method of claim 14, wherein calculating the field produced comprises modeling the plurality of electromagnetic coils in oblate spheroidal coordinate and modeling the field produced using oblate spheroidal harmonics.

18. A magnetic resonance imaging (MRI) magnet system comprising:
a plurality of electromagnetic coils arranged around a magnet opening with a length of 100 cm or less;
wherein the plurality of electromagnetic coils is configured to generate a static magnetic field within a non-spherical field of view (FOV), and wherein the static magnetic field within the FOV has a measure of homogeneity of 100 parts per million or better.

19. A whole-body magnetic resonance imaging (MRI) system for humans comprising:
a magnet opening with a length of less than 100 cm; and
a plurality of electromagnetic coils configured to generate a static magnetic field within a field of view (FOV), wherein the FOV is a non-spherical shape, and wherein the static magnetic field within the FOV has a measure of homogeneity better than 100 parts per million.
